(19) United States
(12) Patent Application Publication
(10) Pub. No.: US 2020/0303440 A1
(43) Pub. Date: Sep. 24, 2020

(54) IMAGE CAPTURING DEVICE, LIQUID DISCHARGE DEVICE, AND IMAGE CAPTURING METHOD

(71) Applicant: Takumi HIRAGA, Kanagawa (JP)

(72) Inventor: Takumi HIRAGA, Kanagawa (JP)

(73) Assignee: Ricoh Company, Ltd., Tokyo (JP)

(21) Appl. No.: 16/819,581

(22) Filed: Mar. 16, 2020

(30) Foreign Application Priority Data
Mar. 19, 2019 (JP) 2019-050651

(51) Int. Cl. H01L 27/146

(52) U.S. Cl. CPC H01L 27/14621; B41J 29/38; H01L 27/14603; H01L 27/14609

(57) ABSTRACT

An image capturing device includes an image capturing unit, a movement control unit, an acquisition unit, and a generation unit. The image capturing unit includes a single-plate image sensor including color filters disposed on two-dimensionally arrayed light receiving elements, and configured to capture an image of an image capturing region on an image capturing target. The movement control unit is configured to move the image capturing region such that images of each of a plurality of pixel areas on the image capturing target are captured by light receiving elements corresponding to respective color filters of colors different from each other. The acquisition unit is configured to acquire image data of the image capturing region each time the image capturing region is moved. The generation unit is configured to generate color image data of the image capturing region from a plurality of pieces of the image data.

### CROSS-REFERENCE TO RELATED APPLICATIONS

The present application claims priority under 35 U.S.C. § 119 to Japanese Patent Application No. 2019-050651, filed on Mar. 19, 2019. The contents of which are incorporated herein by reference in their entirety.

### BACKGROUND OF THE INVENTION

### 1. Field of the Invention

The present invention relates to an image capturing device, a liquid discharge device, and an image capturing method.

### 2. Description of the Related Art

A system configured to acquire a color image of an image capturing target by using a single-plate image sensor including a color filter disposed on a light receiving element has been known. For example, in a known system, obtained image information of each pixel is corrected by using information of pixels nearby to interpolate color information for the pixel, thereby generating color image data.

However, with this technology, decrease of sharpness and false color sometimes occur to an edge area in which brightness abruptly changes. To avoid this, a disclosed system (for example, Japanese Unexamined Patent Application Publication No. 2011-61249) includes a plurality of color filters disposed between the image capturing target and the light receiving element, and switches color components of light incident on the light receiving element by switching the color filters at each image capturing.

However, the conventional technology needs an actuator for switching the filters, which leads to complication of the device, and thus it has been difficult to obtain highly accurate color image data with a simple configuration.

### SUMMARY OF THE INVENTION

According to an aspect of the present invention, an image capturing device includes an image capturing unit, a movement control unit, an acquisition unit, and a generation unit. The image capturing unit includes a single-plate image sensor including color filters disposed on two-dimensionally arrayed light receiving elements. The image capturing unit is configured to capture an image of an image capturing region on an image capturing target. The movement control unit is configured to move the image capturing region such that images of each of a plurality of pixel areas on the image capturing target are captured by light receiving elements corresponding to respective color filters of colors different from each other. The acquisition unit is configured to acquire image data of the image capturing region each time the image capturing region is moved. The generation unit is configured to generate color image data of the image capturing region from a plurality of pieces of the image data.

### BRIEF DESCRIPTION OF THE DRAWINGS

FIG. 1 is a perspective view illustrating an exemplary liquid discharge device;

FIG. 2 is a top view illustrating an exemplary mechanical configuration of the liquid discharge device;

FIG. 3 is a schematic diagram of an exemplary elevation mechanism;

FIG. 4 is an explanatory diagram of a specific example of an image capturing device;

FIG. 5 is an explanatory diagram of a schematic configuration of a control mechanism of the liquid discharge device;

FIG. 6 is a block diagram illustrating an exemplary control mechanism of the image capturing device;

FIG. 7 is an enlarged pattern diagram of color filters of an image sensor;

FIG. 8 is an enlarged pattern diagram of the color filters of the image sensor;

FIG. 9 is a pattern diagram illustrating exemplary demosaicing;

FIG. 10 is a pattern diagram illustrating exemplary demosaicing through linear interpolation;

FIG. 11A is a pattern diagram illustrating an exemplary image capturing region of a pattern in which light and dark parts are alternately repeated;

FIG. 11B is a pattern diagram illustrating exemplary color image data obtained through demosaicing by a conventional scheme;

FIG. 12A is an explanatory diagram of image data obtained at each movement of the image capturing region;

FIG. 12B is an explanatory diagram of image data obtained at each movement of the image capturing region;

FIG. 12C is an explanatory diagram of image data obtained at each movement of the image capturing region;

FIG. 12D is an explanatory diagram of image data obtained at each movement of the image capturing region;

FIG. 13 is a flowchart illustrating an exemplary process of processing executed by a demosaicing unit; and

FIG. 14 is a diagram illustrating an exemplary hardware configuration of an image processing unit.

The accompanying drawings are intended to depict exemplary embodiments of the present invention and should not be interpreted to limit the scope thereof. Identical or similar reference numerals designate identical or similar components throughout the various drawings.

### DESCRIPTION OF THE EMBODIMENTS

The terminology used herein is for the purpose of describing particular embodiments only and is not intended to be limiting of the present invention.

As used herein, the singular forms “a”, “an” and “the” are intended to include the plural forms as well, unless the context clearly indicates otherwise.

In describing preferred embodiments illustrated in the drawings, specific terminology may be employed for the sake of clarity. However, the disclosure of this patent specification is not intended to be limited to the specific terminology so selected, and it is to be understood that each specific element includes all technical equivalents that have the same function, operate in a similar manner, and achieve a similar result.

An embodiment of the present invention will be described in detail below with reference to the drawings.

An embodiment has an object to obtain highly accurate color image data with a simple configuration.

An image capturing device, a liquid discharge device, and an image capturing method according to the present embodiment will be described below in detail with the accompanying drawings. In the present embodiment, the following description is made with an example in which the image capturing device is applied to the liquid discharge device. However, application of the image capturing device is not limited to the liquid discharge device.

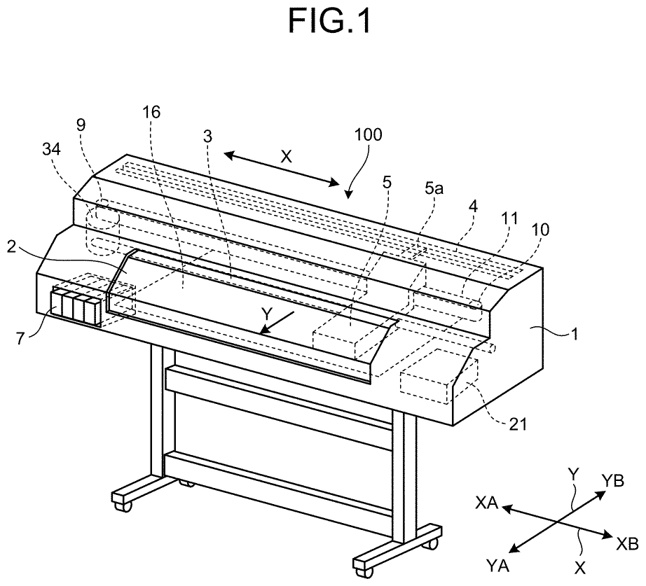

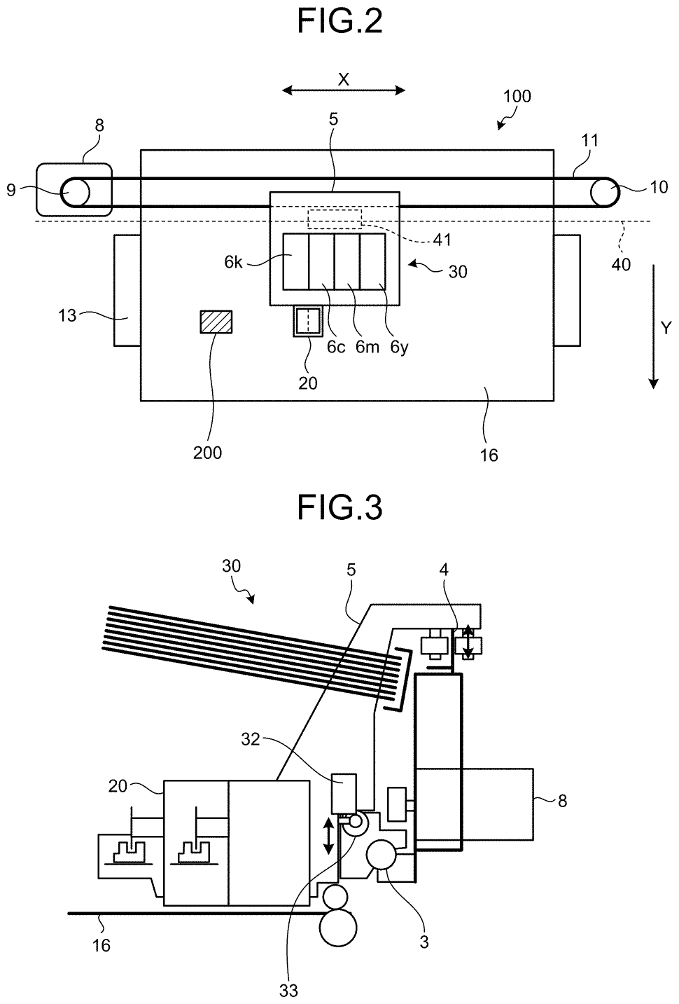

FIG. 1 is a perspective view illustrating an exemplary liquid discharge device 100 according to the present embodiment. FIG. 2 is a top view illustrating an exemplary mechanical configuration of the liquid discharge device 100.

As illustrated in FIG. 1, the liquid discharge device 100 according to the present embodiment includes a carriage 5 configured to form an image on a recording medium 16 reciprocated in a main-scanning direction (the direction of arrow X in FIG. 1, hereinafter referred to as a main-scanning direction X) and intermittently conveyed in a sub-scanning direction (the direction of arrow Y in FIG. 1, hereinafter referred to as a sub-scanning direction Y). The main-scanning direction X is parallel to a two-dimensional plane of the recording medium 16 (in other words, in the plane direction of a platen plate 13). The sub-scanning direction Y is parallel to the two-dimensional plane of the recording medium 16 and orthogonal to the main-scanning direction X.

The recording medium 16 is an exemplary image capturing target. The image capturing target is a target, an image of which is captured by an image capturing unit to be described later. The following description of the present embodiment is made with an example in which the image capturing target is the recording medium 16. However, the image capturing target of the image capturing unit is not limited to the recording medium 16.

The carriage 5 is supported by a main guide rod 3 extended in the main-scanning direction X. The carriage 5 is provided with a coupling piece 5a. The coupling piece 5a is engaged with a sub guide 4 provided in parallel to the main guide rod 3, thereby stabilizing the posture of the carriage 5.

As illustrated in FIG. 2, a plurality of record heads of a record head 6y configured to discharge yellow (Y) ink, a record head 6m configured to discharge magenta (M) ink, a record head 6c configured to discharge cyan (C) ink, and a record head 6k configured to discharge black (Bk) ink (hereinafter, the record heads 6y, 6m, 6c, and 6k are also collectively referred to as a record head 6) are mounted on the carriage 5. The record head 6 is mounted on the carriage 5 with its discharge surface (nozzle surface) facing downward (the recording medium 16 side). The record head 6 is a main image output means.

The description continues with reference to FIG. 1. A cartridge 7 as an ink supply body for supplying ink to the record head 6 is not mounted on the carriage 5 but is disposed at a predetermined position in the liquid discharge device 100. The cartridge 7 and the record head 6 are coupled to each other through a pipe (not illustrated), and ink is supplied from the cartridge 7 to the record head 6 through the pipe.

The carriage 5 is coupled to a timing belt 11 stretched around a drive pulley 9 and a driven pulley 10. The drive pulley 9 is rotated by drive of a main-scanning motor 34. The main-scanning motor 34 is a direct-current (DC) motor. The driven pulley 10 includes a mechanism to adjust its distance to the drive pulley 9 and has a function to provide predetermined tension to the timing belt 11. The carriage 5 is reciprocated in the main-scanning direction X as the timing belt 11 is fed by drive of the main-scanning motor 34. Movement of the carriage 5 in the main-scanning direction X is controlled based on an encoder value obtained when a main-scanning encoder sensor 41 provided to the carriage 5 senses a mark on an encoder sheet 40 as illustrated in, for example, FIG. 2.

The liquid discharge device 100 according to the present embodiment also includes a maintenance mechanism 21 for maintaining reliability of the record head 6. The maintenance mechanism 21 performs, for example, cleaning and capping of the discharge surface of the record head 6, and ejection of unnecessary ink from the record head 6.

As illustrated in FIG. 2, the platen plate 13 is provided at a position facing the discharge surface of the record head 6. The platen plate 13 supports the recording medium 16 when ink is discharged from the record head 6 onto the recording medium 16. The liquid discharge device 100 according to the present embodiment is a wide device in which the travel distance of the carriage 5 in the main-scanning direction X is long. Thus, the platen plate 13 is formed by connecting a plurality of plate members in the main-scanning direction X (the moving direction of the carriage 5). The recording medium 16 is sandwiched by conveyance rollers driven by a sub-scanning motor (not illustrated) and is intermittently conveyed on the platen plate 13 in the sub-direction scanning Y. The sub-scanning motor is a direct-current (DC) motor. In addition, a sub-scanning encoder sensor (not illustrated) is provided to the liquid discharge device 100 and acquires the amount of movement in the sub-scanning direction Y as a slit plate is rotated along with rotation of the conveyance rollers.

The record head 6 includes a plurality of nozzle lines. An image is formed on the recording medium 16 by discharging ink from the nozzle lines onto the recording medium 16 being conveyed on the platen plate 13.

The above-described components included in the liquid discharge device 100 according to the present embodiment are disposed inside an exterior body 1. The exterior body 1 is provided with a cover member 2 that can be opened and closed. At maintenance of the liquid discharge device 100 or occurrence of paper jam, the cover member 2 is opened to perform work on a component provided inside the exterior body 1.

The liquid discharge device 100 according to the present embodiment intermittently conveys the recording medium 16 in the sub-scanning direction Y and ejects ink onto the recording medium 16 on the platen plate 13 from the nozzle lines of the record head 6 mounted on the carriage 5 while moving the carriage 5 in the main-scanning direction X while conveyance of the recording medium 16 in the sub-scanning direction Y is stopped, thereby forming an image on the recording medium 16.

The liquid discharge device 100 according to the present embodiment also includes an elevation mechanism 30. FIG. 3 is a schematic diagram of an exemplary elevation mechanism 30. When the recording medium 16 is, for example, a highly elastic sheet or a bent sheet, the recording medium 16 is likely to float over the platen plate 13. In such a case, the record head 6 is potentially damaged and broken by the recording medium 16. To avoid this, the liquid discharge device 100 according to the present embodiment includes the elevation mechanism 30 configured to move up and down the carriage 5. The elevation mechanism 30 includes a carriage elevation motor 32 and a carriage elevation cam 33. The elevation mechanism 30 moves up and down the carriage 5 as the carriage elevation cam 33 is rotated by drive of the carriage elevation motor 32. The elevation mechanism 30 of the carriage 5 is not limited to the configuration illustrated in FIG. 3.

The liquid discharge device 100 according to the present embodiment includes an image capturing device 20. The image capturing device 20 obtains image data by capturing an image of an image capturing region on the recording medium 16 as an exemplary image capturing target.

As illustrated in FIG. 2, the image capturing device 20 is fixed to the carriage 5 and reciprocated integrally with the carriage 5 in the main-scanning direction X. The image capturing device 20 captures an image of the image capturing region of the recording medium 16 and obtains image data of one frame at each image capturing.

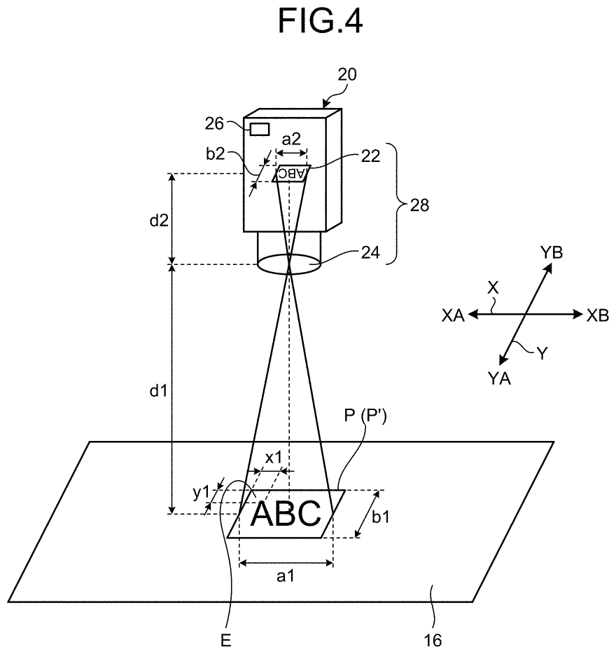

FIG. 4 is an explanatory diagram of a specific example of the image capturing device 20.

The image capturing device 20 includes an image processing unit 26 and an image capturing unit 28. The image processing unit 26 executes various kinds of image processing on image data obtained by the image capturing unit 28 (described later in detail). The image capturing unit 28 obtains image data by capturing an image of an image capturing region P of the recording medium 16.

The image capturing unit 28 includes an image sensor 22 and a lens 24. The image sensor 22 is a single-plate image sensor including color filters disposed on two-dimensionally arrayed light receiving elements.

Each light receiving element is a well-known photoelectric conversion element configured to output a signal in accordance with the intensity of received light. The light receiving element is, for example, a charge-coupled device (CCD) or a complementary metal-oxide-semiconductor (CMOS).

In the single-plate image sensor, a color filter of any one of three primary colors such as RGB is disposed on each light receiving element. Thus, each light receiving element obtains color information of any one of RGB colors through single image capturing.

In the image sensor 22, a filter made of color filters of a plurality of colors are disposed along a two-dimensional plane on which the light receiving elements are two-dimensionally arrayed. For example, the filter includes a Bayer array of color filters of RGB colors on the above-described two-dimensional plane. Alternatively, for example, the filter includes a complementary color filter array of color filters of CMYG colors on the above-described two-dimensional plane. The Bayer array is also referred to as a primary color filter array. The complementary color filter array is also referred to as a checker color array.

The following description of the present embodiment is made with an example in which the image sensor 22 includes a Bayer array of RGB color filters along a two-dimensional plane on which the light receiving elements are two-dimensionally arrayed.

The image capturing unit 28 is attached to the carriage 5 so that the image capturing unit 28 can capture an image of the image capturing region P on the recording medium 16.

Specifically, the lens 24 of the image capturing unit 28 is disposed so that the optical axis of the lens 24 is aligned with a line perpendicular to the surface of the recording medium 16 being conveyed on the platen plate 13. Specifically, the image capturing unit 28 is attached to the carriage 5 to satisfy this relation. In addition, the image sensor 22 of the image capturing unit 28 is disposed so that the optical axis of the lens 24 is aligned with a line orthogonal to the two-dimensional plane of the light receiving elements provided to the image sensor 22.

With this configuration, the image sensor 22 can obtain image data by capturing an image of the image capturing region P on the recording medium 16.

The positional relation between the image capturing device 20 and the recording medium 16 satisfies the following relation.

The size of the image capturing region P on the recording medium 16 in the main-scanning direction X is represented by a1. The image capturing region P is a region on the recording medium 16 that the image capturing device 20 can capture an image at single image capturing. The size of the two-dimensional plane on which the light receiving elements of the image sensor 22 are arrayed in the main-scanning direction X is represented by a2. The distance between the lens 24 and the recording medium 16 is represented by d1. The distance between the lens 24 and the two-dimensional plane of the image sensor 22 is represented by d2. With this notation, the relation of Expression (1) below holds.

a1=a2×d1/d2 (1)

The number of pixels of the two-dimensional plane on which the light receiving elements of the image sensor 22 are arrayed in the main-scanning direction X is represented by x2. The size corresponding to each pixel in the image capturing region P in the main-scanning direction X is represented by x1. With this notation, the relation of Expression (2) below holds.

x1=a1/x2 (2)

The size of the image capturing region P on the recording medium 16 in the sub-scanning direction Y is represented by b1. The size of the two-dimensional plane on which the light receiving elements of the recording medium 16 are arrayed in the sub-scanning direction Y is represented by b2. The distance between the lens 24 and the recording medium 16 is represented by d1. The distance between the lens 24 and the two-dimensional plane of the image sensor 22 is represented by d2. With this notation, the relation of Expression (3) below holds.

b1=b2×d1/d2 (3)

The number of pixels of the two-dimensional plane on which the light receiving elements of the image sensor 22 are arrayed in the sub-scanning direction Y is represented by y2. The size corresponding to each pixel in the image capturing region P in the sub-scanning direction Y is represented by y1. With this notation, the relation of Expression (4) below holds.

y1=b1/y2 (4)

In the present embodiment, the image processing unit 26 executes image processing to be described later by using these expressions (described later in detail).

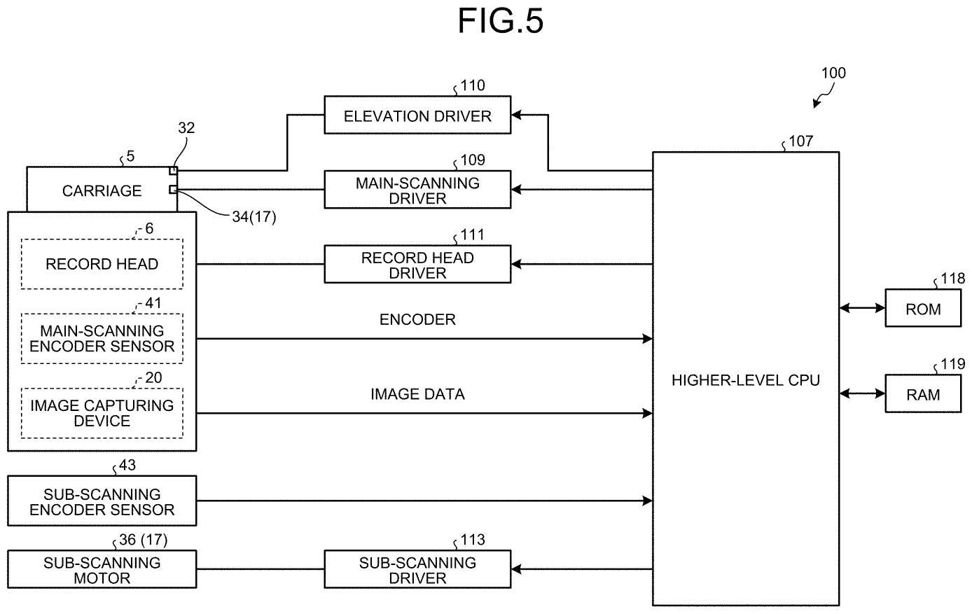

FIG. 5 is an explanatory diagram of a schematic configuration of a control mechanism of the liquid discharge device 100 according to the present embodiment.

The control mechanism of the liquid discharge device 100 according to the present embodiment includes a higher-level CPU 107, a ROM 118, a RAM 119, an elevation driver 110, a main-scanning driver 109, a record head driver 111, a sub-scanning driver 113, the carriage 5, the record head 6, the main-scanning encoder sensor 41, the image capturing device 20, and a sub-scanning motor 36. The record head 6, the main-scanning encoder sensor 41, and the image capturing device 20 are mounted on the carriage 5 as described above.

The higher-level CPU 107 governs the entire control of the liquid discharge device 100 by supplying data of an image to be formed on the recording medium 16 and a drive control signal (pulse signal) to each driver. Specifically, the higher-level CPU 107 controls elevation of the carriage 5 by driving the carriage elevation motor 32 through the elevation driver 110. The higher-level CPU 107 also controls drive of the carriage 5 in the main-scanning direction by controlling the main-scanning motor 34 through the main-scanning driver 109. The higher-level CPU 107 also controls the timing of ink discharge by the record head 6 through the record head driver 111. The higher-level CPU 107 also controls drive of the sub-scanning motor 36 through the sub-scanning driver 113.

The main-scanning motor 34 and the sub-scanning motor 36 are each an exemplary first drive unit. The first drive unit relatively moves at least one of the recording medium 16 as the image capturing target and the image capturing device 20 in the main-scanning direction X and the sub-scanning direction Y. In the present embodiment, as described above, the main-scanning motor 34 moves the carriage 5 in the main-scanning direction X. Thus, the image capturing device 20 moves in the main-scanning direction X along with movement of the carriage 5 in the main-scanning direction X. In the present embodiment, as described above, the sub-scanning motor 36 moves the recording medium 16 in the sub-scanning direction Y.

The carriage elevation motor 32 is an exemplary second drive unit. The second drive unit changes the distance between the recording medium 16 as the image capturing target and the image capturing device 20. As described above, the carriage elevation motor 32 moves up and down the carriage 5 by drive of the carriage elevation motor 32. Thus, in the present embodiment, the distance between the carriage 5 and the recording medium 16 is changed by drive of the carriage elevation motor 32.

The main-scanning encoder sensor 41 outputs, to the higher-level CPU 107, an encoder value obtained by sensing a mark on the encoder sheet 40. The higher-level CPU 107 controls drive of the carriage 5 in the main-scanning direction X through the main-scanning driver 109 based on the encoder value from the main-scanning encoder sensor 41. In addition, a sub-scanning encoder sensor 43 outputs an acquired movement amount in the sub-scanning direction Y to the higher-level CPU 107. The higher-level CPU 107 controls drive in the sub-scanning direction Y based on the movement amount from the sub-scanning encoder sensor 43. The liquid discharge device 100 may control drive (scanning) in the main-scanning direction X and the sub-scanning direction Y by using a stepping motor. In this case, the liquid discharge device 100 may include no encoder sensors (the main-scanning encoder sensor 41 nor the sub-scanning encoder sensor 43).

The image capturing device 20 captures an image of the image capturing region P of the recording medium 16 and obtains image data of one frame at each image capturing. Then, the image processing unit 26 executes various kinds of image processing on a plurality of pieces of the obtained image data and outputs color image data.

The ROM 118 stores, for example, computer programs and various kinds of control data of the procedure of processing executed by the higher-level CPU 107. The RAM 119 is used as a working memory of the higher-level CPU 107.

The following describes the image capturing device 20 in detail.

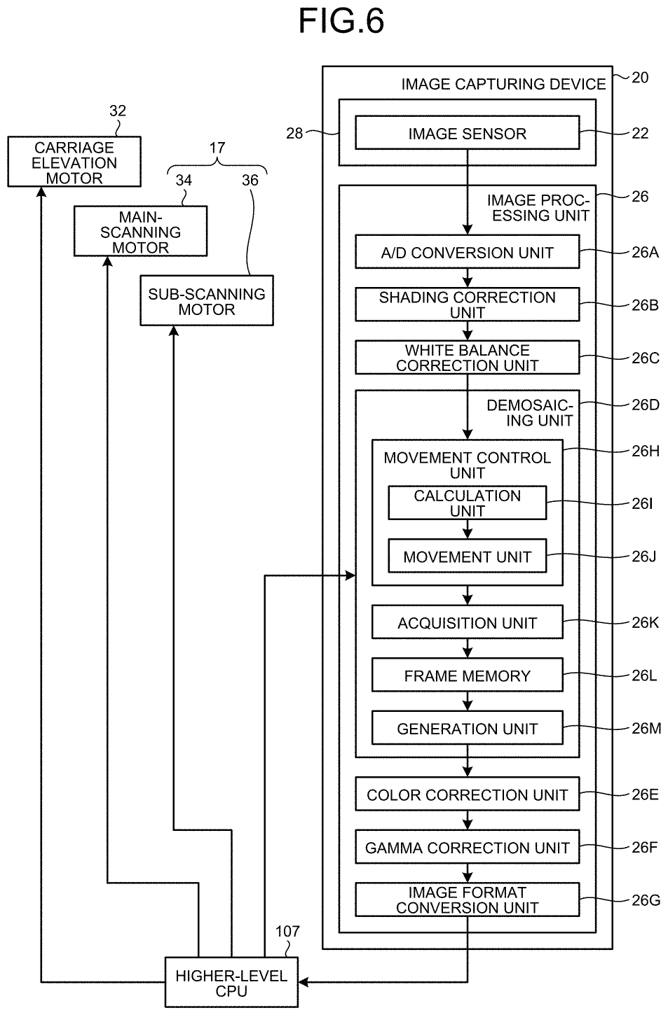

FIG. 6 is a block diagram illustrating an exemplary control mechanism of the image capturing device 20.

The image capturing device 20 includes the image capturing unit 28 and the image processing unit 26. The image capturing unit 28 and the image processing unit 26 are connected with each other to perform communication of data or signals therebetween.

The image capturing unit 28 is provided with the image sensor 22. The image capturing unit 28 captures an image of the image capturing region P on the recording medium 16. The image capturing unit 28 may further have at least part of the function of the image processing unit 26.

The image processing unit 26 executes various kinds of image processing on image data received from the image sensor 22. In the present embodiment, the image processing unit 26 includes an analog-digital (A/D) conversion unit 26A, a shading correction unit 26B, a white balance correction unit 26C, a demosaicing unit 26D, a color correction unit 26E, a gamma correction unit 26F, and an image format conversion unit 26G.

The A/D conversion unit 26A converts an analog signal received by the image sensor 22 into image data as digital data. The shading correction unit 26B corrects illumination unevenness of the image data due to variation in the sensitivity of the light receiving elements and difference in the angle of incident light on the light receiving elements. The white balance correction unit 26C corrects white balance of the image data. The demosaicing unit 26D generates color image data by using the image data (described later in detail). The color correction unit 26E provides the color image data with color correction to make spectral characteristics of the color filters closer to ideal characteristics. The gamma correction unit 26F performs γ correction of the color image data provided with the color correction by the color correction unit 26E. The image format conversion unit 26G converts the color image data provided with the γ correction into an optional format. Then, the image format conversion unit 26G outputs the color image data provided with the format conversion to the higher-level CPU 107.

The following describes the processing at the demosaicing unit 26D.

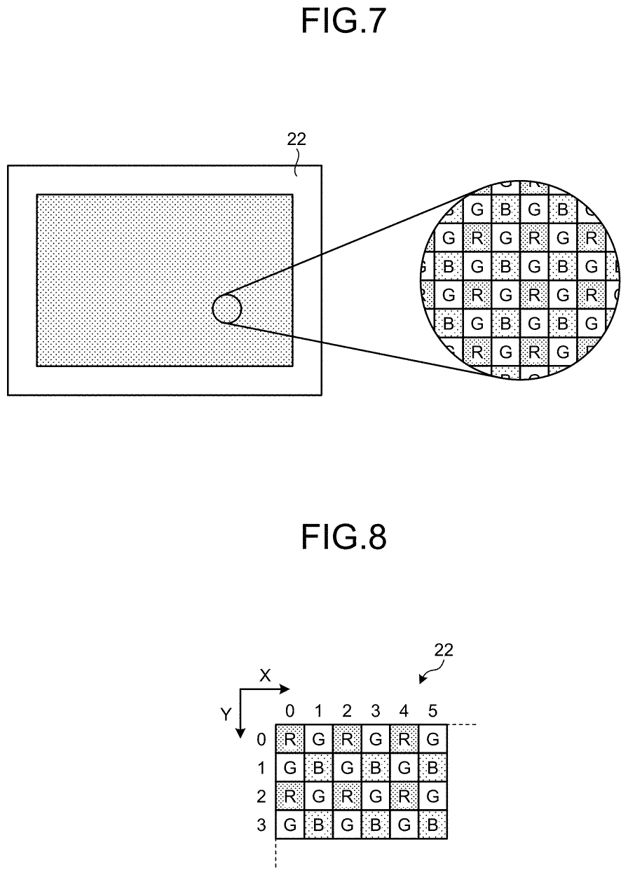

The description is first made on overview of processing at a conventional demosaicing unit. FIGS. 7 and 8 are enlarged pattern diagrams of the color filters of the image sensor 22. For example, the image sensor 22 includes a Bayer array of RGB color filters along the two-dimensional plane on which the light receiving elements are two-dimensionally arrayed. As described above, the image sensor 22 is a single-plate image sensor in which a color filter of any one of three primary colors such as RGB is disposed on each light receiving element. In other words, one color filter of R, G, or B color is disposed on each light receiving element.

Thus, each pixel included in image data of one frame obtained from the image sensor 22 only has color information of one color and lacks color information of the remaining two colors.

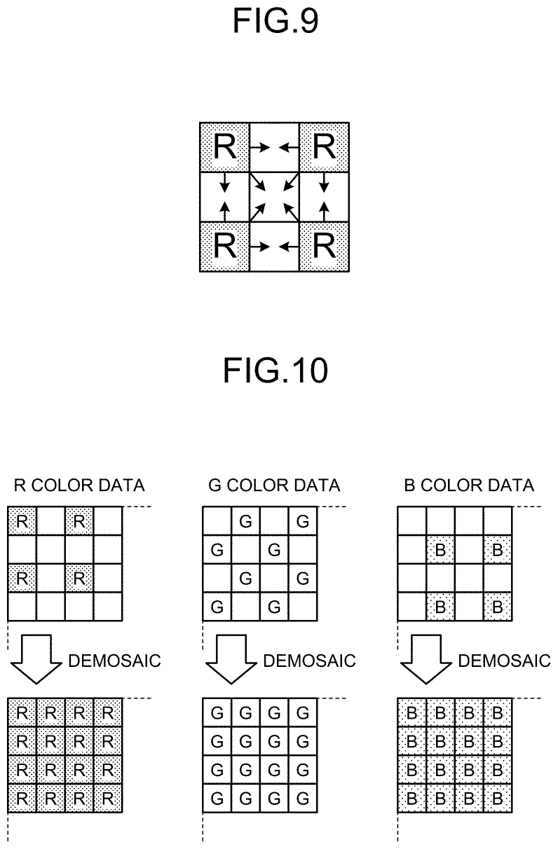

FIG. 9 is a pattern diagram illustrating exemplary demosaicing. As illustrated in FIG. 9, the demosaicing unit executes, for each pixel included in image data, interpolation processing that interpolates the lacking color information by using color information of other pixels nearby. The interpolation processing is also referred to as demosaicing.

FIG. 10 is a pattern diagram illustrating exemplary demosaicing through linear interpolation. For example, the demosaicing unit linearly interpolates the pixel value of a pixel having no R (red) color information by using the pixel value of a pixel having R color information in the image data. Similarly, the demosaicing unit linearly interpolates the pixel value of a pixel having no G (green) color information by using the pixel value of a pixel having G color information in the image data. Similarly, the demosaicing unit linearly interpolates the pixel value of a pixel having no B (blue) color information by using the pixel value of a pixel having B color information in the image data. The interpolation method is not limited to linear interpolation.

Through these pieces of interpolation processing, the demosaicing unit generates, for each pixel, color image data having color information of all RGB colors.

Highly accurate color image data can be obtained by the above-described demosaicing when color and luminance are uniform in the image capturing region P. However, color image data largely deviated from actual color information is obtained when at least one of color and luminance is non-uniform in the image capturing region P. The case in which at least one of color and luminance is non-uniform in the image capturing region P is, for example, a case in which the image capturing region P is an image including fine patterns and edges.

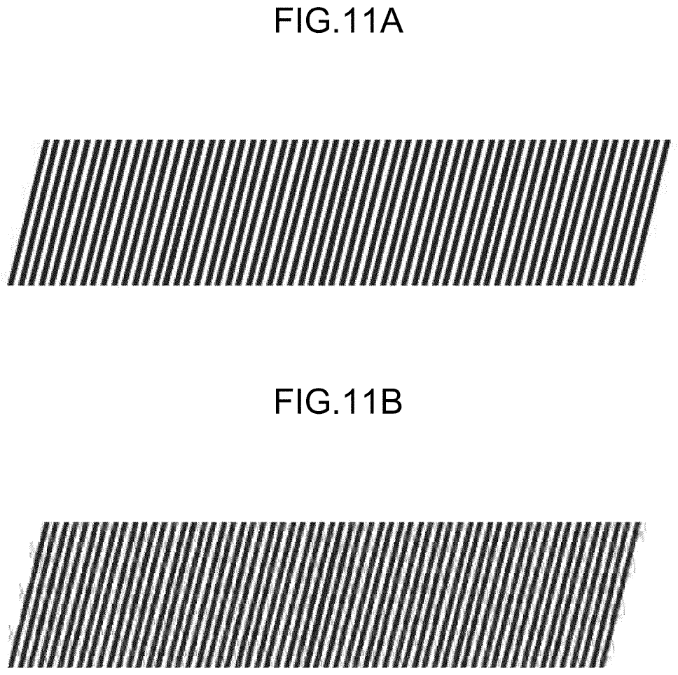

FIG. 11A is a pattern diagram illustrating an exemplary image capturing region of a pattern in which light and dark parts are alternately repeated. FIG. 11B is a pattern diagram illustrating exemplary color image data obtained through demosaicing in the above-described conventional scheme. When image capturing is performed on the image capturing region illustrated in FIG. 11A and demosaicing is performed by the above-described conventional method, color shift (false color) and blur, which do not exist in the image capturing region, potentially occur as illustrated in FIG. 11B.

The description continues with reference to FIG. 6. To solve the above-described problem, the demosaicing unit 26D according to the present embodiment includes a movement control unit 26H, an acquisition unit 26K, a frame memory 26L, and a generation unit 26M.

The movement control unit 26H moves the image capturing region P so that an image of each of a plurality of pixel areas on the recording medium 16 is captured by a light receiving element corresponding to one of the color filters of a plurality of colors different from each other. The movement control unit 26H does not necessarily need to be provided to the demosaicing unit 26D. The movement control unit 26H may be provided to, for example, the higher-level CPU 107.

Each pixel area on the recording medium 16 corresponds to one of the light receiving elements of the image sensor 22. In other words, each pixel area on the recording medium 16 is an area on the recording medium 16, an image of which is captured by one light receiving element. In the configuration illustrated in FIG. 4, each pixel area is an area of x1×y1 on the recording medium 16, which has a size of x1 in the main-scanning direction X and a size of y1 in the sub-scanning direction Y (refer to area E in FIG. 4).

As described above, the image sensor 22 is a single-plate image sensor in which a color filter of any one of three primary colors such as RGB is disposed on each light receiving element. In other words, one color filter of R, G, or B color is disposed on each light receiving element.

In the present embodiment, the movement control unit 26H moves the image capturing region P at each image capturing (of one frame) so that an image of each pixel area on the recording medium 16 is captured by one of the light receiving elements corresponding to the respective color filters of the three colors of RGB (in other words, light receiving elements different from each other).

Specifically, the movement control unit 26H includes a calculation unit 26I and a movement unit 26J. The calculation unit 26I calculates the amount of each movement of the image capturing region P in at least one of the main-scanning direction X and the sub-scanning direction Y based on the array interval of the light receiving elements of the image sensor 22 and the distance between the image capturing unit 28 and the recording medium 16.

Specifically, as described above, the calculation unit 26I calculates the size x1 corresponding to one pixel in the image capturing region P in the main-scanning direction X as the amount of movement in the main-scanning direction X by using Expressions (1) and (2) described above. In addition, as described above, the calculation unit 26I calculates the size y1 corresponding to one pixel in the image capturing region P in the sub-scanning direction Y as the amount of movement in the sub-scanning direction Y by using Expressions (3) and (4) described above.

The amount of movement in each of the main-scanning direction X and the sub-scanning direction Y may be any movement amount with which image capturing is performed by light receiving elements corresponding to color filters of colors different from each other, and is not limited to a size corresponding to one pixel in the image capturing region P.

The calculation unit 26I may calculate the amount of movement in each of the main-scanning direction X and the sub-scanning direction Y in advance and store the calculated amount of movement in a storage unit.

Then, the movement unit 26J moves the image capturing region P by the calculated amount of movement. Specifically, the movement unit 26J controls a first drive unit 17 (the main-scanning motor 34 and the sub-scanning motor 36) to move the image capturing region P by the calculated amount of movement.

The acquisition unit 26K acquires the image data of the image capturing region P each time the image capturing region P is moved. Specifically, each time the image capturing region P is moved, the acquisition unit 26K acquires the image data input from the image sensor 22 and corrected by the A/D conversion unit 26A, the shading correction unit 26B, and the white balance correction unit 26C.

For example, the movement control unit 26H moves, for each image capturing area P′ on the recording medium 16, the image capturing region P in a first main-scanning direction XA as one of directions along the main-scanning direction X, in a first sub-scanning direction YA as one of directions along the sub-scanning direction Y, and then in a second main-scanning direction XB as the other direction along the main-scanning direction X (refer to FIG. 4).

The movement in the first main-scanning direction XA and the second main-scanning direction XB is achieved by movement of the carriage 5 in the main-scanning direction X. The movement in the sub-scanning direction Y is achieved by movement of the recording medium 16 in the sub-scanning direction Y. For example, the recording medium 16 is conveyed in a second sub-scanning direction YB as one of directions along the sub-scanning direction Y (refer to FIGS. 1 and 4). In this case, the image capturing region P is moved in the first sub-scanning direction YA as the other direction along the sub-scanning direction Y by conveying the recording medium 16 in the second sub-scanning direction YB.

The image capturing area P′ is a area on the recording medium 16 as the unit of movement of the image capturing region P. The movement control unit 26H sets a plurality of image capturing areas P′ at least partially overlapping with each other on the recording medium 16. Then, the movement control unit 26H moves, for each image capturing area P′, the image capturing region P so that an image of each of a plurality of pixel areas included in the image capturing area P′ is captured by a light receiving element corresponding to one of the color filters of a plurality of colors different from each other. Then, the acquisition unit 26K acquires the image data of the image capturing region P each time the image capturing region P is moved.

Accordingly, the acquisition unit 26K acquires, for each image capturing area P′, the image data indicating R color information, the image data indicating G color information, and the image data indicating B color information.

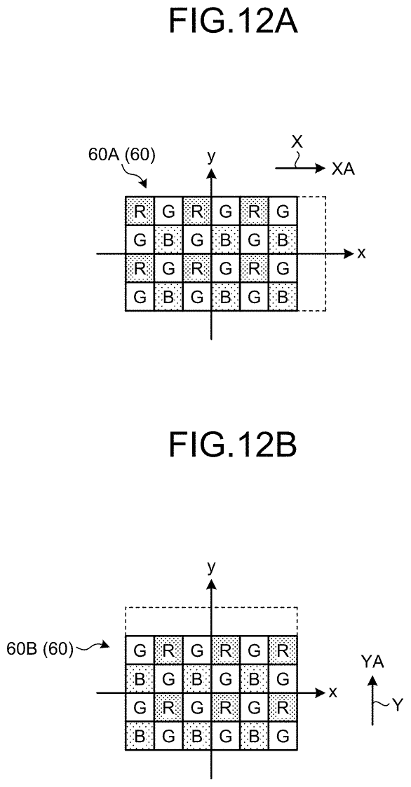

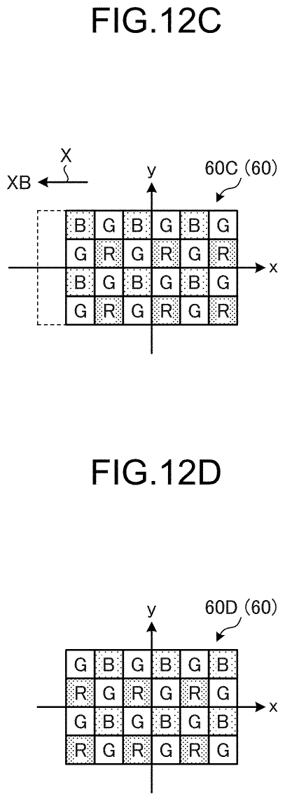

Specific description is made with reference to FIGS. 12A to 12D. FIGS. 12A to 12D are each an explanatory diagram of image data 60 obtained at each movement of the image capturing region P.

For example, the acquisition unit 26K acquires image data 60A illustrated in FIG. 12A as the image data 60 of the image capturing region P. The movement control unit 26H moves the image capturing region P, for example, by the movement amount “x1” in the first main-scanning direction XA. Then, the acquisition unit 26K acquires the image data of the image capturing region P at a position to which the movement is made. Accordingly, image data 60B illustrated in FIG. 12B is obtained. In the image data 60B, the positions of the color filters (light receiving elements) of the image sensor 22 relative to the recording medium 16 are moved from those in the image data 60A by one pixel (one light receiving element) in the first main-scanning direction XA.

Subsequently, the movement control unit 26H moves the image capturing region P by the movement amount “y1” in the first sub-scanning direction YA. The movement control unit 26H conveys the recording medium 16 by the movement amount “y1” in the second sub-scanning direction YB. Through this conveyance, the image capturing region P is moved in the first sub-scanning direction YA as the opposite direction along the sub-scanning direction Y.

Then, the acquisition unit 26K acquires the image data of the image capturing region P at a position to which the movement is made. Accordingly, image data 60C illustrated in FIG. 12C is obtained. In the image data 60C, the positions of the color filters (light receiving elements) of the image sensor 22 relative to the recording medium 16 are moved from those in the image data 60B by one pixel (one light receiving element) in the first sub-scanning direction YA.

Subsequently, the movement control unit 26H moves the image capturing region P by the movement amount “x1” in the second main-scanning direction XB. Then, the acquisition unit 26K acquires the image data of the image capturing region P at a position to which the movement is made. Accordingly, image data 60D illustrated in FIG. 12D is obtained. In the image data 60D, the positions of the color filters (light receiving elements) of the image sensor 22 relative to the recording medium 16 are moved from those in the image data 60C by one pixel (one light receiving element) in the second main-scanning direction XB.

In this manner, the image data 60 in which the positions of the color filters relative to the recording medium 16 are shifted by one pixel (one light receiving element) is obtained for each image capturing area P′ under control of the movement control unit 26H. As described above, the amount of movement may be any amount with which images of the pixel areas (areas E) on the recording medium 16 are captured by the light receiving elements corresponding to the respective color filters different from each other at each movement, and is not limited to one pixel.

The description continues with reference to FIG. 6. Each time the image capturing region P is moved, the acquisition unit 26K acquires the image data of the image capturing region P and stores the acquired image data in the frame memory 26L.

The generation unit 26M generates the color image data of the image capturing region P from a plurality of pieces of the image data.

In the present embodiment, the generation unit 26M generates, for each image capturing area P′, the color image data from a plurality of pieces of the image data.

As described above, the pieces of the image data each include color information of any one of R, G, and B colors for a pixel area included in the image capturing area P′. Thus, the generation unit 26M obtains color information of a plurality of colors by reading, for each pixel, color information of the corresponding pixel position in the pieces of the image data. Then, the generation unit 26M generates, for each pixel, color image data in which color information of a plurality of colors (in other words, RGB colors) is defined.

In this manner, the generation unit 26M generates color image data in which actually obtained color information of RGB colors is defined for each pixel. Accordingly, the demosaicing unit 26D can generate highly accurate color image data with reduced generation of calculation error due to the interpolation processing, color shift (false color), and blur.

When the filter includes a Bayer array of color filters of RGB colors on the two-dimensional plane of the light receiving elements of the image sensor 22, two pieces of G color information corresponding to each pixel area are obtained in some cases. In this case, one of the pieces of G color information may be used.

In the present embodiment, the image capturing device 20 includes no focusing mechanism, and thus is a fixed-focal-point device with fixed focusing. For example, in the image capturing device 20, the focal position of the lens 24 provided to the image capturing device 20 is at the position of the platen plate 13. Thus, non-focused and blurred image data is obtained when the recording medium 16 having a large thickness is placed on the platen plate 13.

To avoid this, the acquisition unit 26K controls the carriage elevation motor 32 as the second drive unit to acquire image data in which the focal point of the image capturing device 20 coincides with the recording medium 16. As described above, the carriage 5 is moved up and down by drive of the carriage elevation motor 32, and the distance between the carriage 5 and the recording medium 16 is changed.

Then, the acquisition unit 26K may acquire image data in which the focal position of the image capturing device 20 is on the recording medium 16.

For example, the position of the image capturing device 20 is fixed in the main-scanning direction X and the sub-scanning direction Y. Then, in this state, the acquisition unit 26K controls the carriage elevation motor 32 to change the distance between the image capturing device 20 and the recording medium 16, thereby acquiring a plurality of pieces of image data. Then, among the acquired pieces of image data, a piece of image data in which the focal point is matched (focusing is achieved) most may be used to generate color image data. In addition, the acquisition unit 26K may fix the distance between the image capturing device 20 and the recording medium 16 to the distance at which the image data with the matched focal point is obtained, and may execute the subsequent processing.

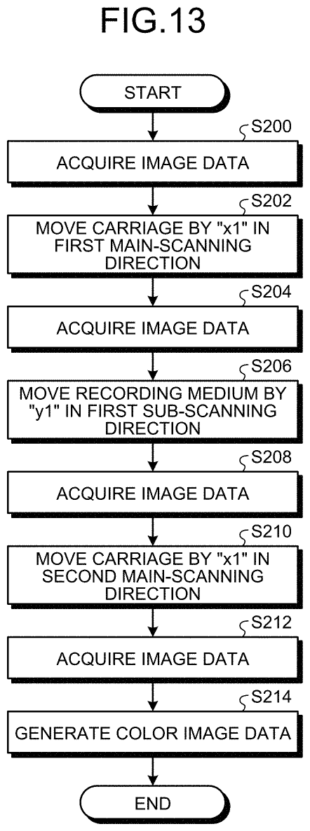

The following describes exemplary processing executed by the demosaicing unit 26D of the image processing unit 26 according to the present embodiment. FIG. 13 is a flowchart illustrating an exemplary process of processing executed by the demosaicing unit 26D.

The following description assumes that the calculation unit 26I calculates and stores the amount of movement in each of the main-scanning direction X and the sub-scanning direction Y in advance. The demosaicing unit 26D executes processing at steps S200 to S214 for each image capturing area P′ of the recording medium 16.

First, the acquisition unit 26K acquires the image data 60A of the image capturing region P (step S200). Through the processing at step S200, the acquisition unit 26K acquires, for example, the image data 60A illustrated in FIG. 12A. The acquisition unit 26K stores the acquired image data 60A in the frame memory 26L.

The movement control unit 26H moves the image capturing region P by the movement amount “x1” in the first main-scanning direction XA (step S202). Specifically, the movement control unit 26H moves the image capturing region P of the image capturing device 20 by moving the carriage 5 by the movement amount “x1” in the first main-scanning direction XA.

The acquisition unit 26K acquires the image data of the image capturing region P at a position to which the movement is made at step S202 (step S204). For example, the acquisition unit 26K acquires the image data 60B illustrated in FIG. 12B. The acquisition unit 26K stores the image data 60B in the frame memory 26L.

Subsequently, the movement control unit 26H moves the image capturing region P by the movement amount “y1” in the first sub-scanning direction YA (step S206). Specifically, the movement control unit 26H conveys the recording medium 16 by the movement amount “y1l” in the second sub-scanning direction YB. Through this conveyance, the image capturing region P is moved in the first sub-scanning direction YA as the opposite direction along the sub-scanning direction Y.

The acquisition unit 26K acquires the image data 60C of the image capturing region P at a position to which the movement is made at step S206 (step S208). For example, the acquisition unit 26K acquires the image data 60C illustrated in FIG. 12C. The acquisition unit 26K stores the acquired image data 60C in the frame memory 26L.

The movement control unit 26H moves the image capturing region P by the movement amount “x1” in the second main-scanning direction XB (step S210). Specifically, the movement control unit 26H moves the image capturing region P of the image capturing device 20 by moving the carriage 5 by the movement amount “x1” in the second main-scanning direction XB.

The acquisition unit 26K acquires the image data of the image capturing region P at a position to which the movement is made at step S210 (step S212). For example, the acquisition unit 26K acquires the image data 60C illustrated in FIG. 12C. The acquisition unit 26K stores the image data 60C in the frame memory 26L.

Subsequently, the generation unit 26M generates the color image data of the image capturing region P from the pieces of the image data 60 (the image data 60A, the image data 60B, the image data 60C, and the image data 60D) obtained through the above-described processing (step S214). Then, the present routine is ended.

As described above, the liquid discharge device 100 according to the present embodiment includes the image capturing unit 28, the movement control unit 26H, the acquisition unit 26K, and the generation unit 26M. The image capturing unit 28 includes the single-plate image sensor 22 including color filters disposed on two-dimensionally arrayed light receiving elements, and captures an image of the image capturing region P on the image capturing target (recording medium 16). The movement control unit 26H moves the image capturing region P such that images of each of a plurality of pixel areas (areas E) on the image capturing target (recording medium 16) are captured by the light receiving elements corresponding to the respective color filters of a plurality of colors different from each other. The acquisition unit 26K acquires the image data of the image capturing region P each time the image capturing region P is moved. The generation unit 26M generates the color image data of the image capturing region P from a plurality of pieces of the image data 60.

The pieces of the image data 60 used to generate the color image data each include color information of any one of R, G, and B colors for each pixel area included in the image capturing area P′. Thus, the generation unit 26M obtains color information of a plurality of colors by reading, for each pixel, color information of the corresponding pixel position in the pieces of the image data. Then, the generation unit 26M generates, for each pixel, color image data in which color information of a plurality of colors (in other words, RGB colors) is defined.

Specifically, in the present embodiment, the generation unit 26M generates color image data in which actually obtained color information of RGB colors is defined for each pixel. Accordingly, the acquisition unit 26K can generate highly accurate color image data with reduced generation of calculation error due to the interpolation processing, color shift (false color), and blur.

The liquid discharge device 100 according to the present embodiment does not need, for example, a mechanism for switching a plurality of filters at each image capturing.

Thus, the liquid discharge device 100 according to the present embodiment can obtain highly accurate color image data with a simple configuration.

The liquid discharge device 100 according to the present embodiment also includes the first drive unit 17 (the main-scanning motor 34, the sub-scanning motor 36) configured to relatively move at least one of the image capturing target (recording medium 16) and the image capturing unit 28 in the main-scanning direction X and the sub-scanning direction Y orthogonal to the main-scanning direction X. The movement control unit 26H controls the first drive unit 17 to move the image capturing region P.

The movement control unit 26H includes the calculation unit 26I configured to calculate the amount of each movement of the image capturing region P in at least one of the main-scanning direction X and the sub-scanning direction Y based on the array interval of the light receiving elements of the image sensor 22 and the distance between the image capturing unit 28 and the image capturing target (recording medium 16), and the movement unit 26J configured to move the image capturing region P by the amount of movement.

The movement control unit 26H moves, for each image capturing area P′ on the image capturing target (recording medium 16), the image capturing region P in the first main-scanning direction XA as one of directions along the main-scanning direction X, in the first sub-scanning direction YA as one of directions along the sub-scanning direction Y, and then in the second main-scanning direction XB as the other direction along the main-scanning direction X. The acquisition unit 26K acquires, for each image capturing area P′, the image data for each movement of the image capturing region P. The generation unit 26M generates, for each image capturing area P′, color image data from the pieces of the image data.

The liquid discharge device 100 according to the present embodiment also includes the second drive unit (carriage elevation motor 32) configured to change the distance between the image capturing target (recording medium 16) and the image capturing unit 28. The acquisition unit 26K controls the second drive unit (carriage elevation motor 32) to acquire the image data in which the focal point of the image capturing unit 28 coincides with the image capturing target (recording medium 16).

The image sensor 22 includes a Bayer array of the color filters of RGB colors.

Alternatively, the image sensor 22 includes a complementary color filter arrayed of color filters of CMYG colors.

The liquid discharge device 100 includes the image capturing device 20, and the record head 6 configured to discharge liquid onto the recording medium 16 as the image capturing target.

The image capturing method according to the present embodiment is performed by a computer, the image capturing method including: moving, by the image capturing unit 28 that includes the single-plate image sensor 22 including color filters disposed on two-dimensionally arrayed light receiving elements and is configured to capture an image of the image capturing region P on the image capturing target (recording medium 16), the image capturing region P such that images of each of a plurality of pixel areas on the image capturing target (recording medium 16) are captured by the light receiving elements corresponding to the respective color filters of a plurality of colors different from each other; acquiring the image data of the image capturing region P each time the image capturing region P is moved; and generating color image data of the image capturing region P from a plurality of pieces of the image data.

The following describes an exemplary hardware configuration of the image processing unit 26.

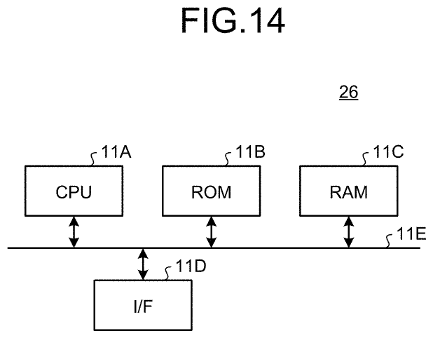

FIG. 14 is a diagram illustrating an exemplary hardware configuration of the image processing unit 26.

The image processing unit 26 has a hardware configuration of a normal computer, in which a central processing unit (CPU) 11A, a read only memory (ROM) 11B, a random access memory (RAM) 11C, an I/F 11D, and the like are connected with each other through a bus 11E.

The CPU 11A is an arithmetic device configured to control the image processing unit 26 according to the present embodiment. The ROM 11B stores, for example, a computer program that achieves various kinds of processing performed by the CPU 11A. The RAM 11C stores data necessary for various kinds of processing performed by the CPU 11A. The I/F 11D is an interface for transmitting and receiving data.

A computer program for executing processing executed by the image processing unit 26 according to the present embodiment is incorporated in the ROM 11B or the like in advance and provided. The computer program executed by the image processing unit 26 according to the present embodiment may be recorded and provided as a file of a format installable or executable on the image processing unit 26 on a computer-readable recording medium such as a CD-ROM, a flexible disk (FD), a CD-R, or a digital versatile disc (DVD).

The embodiment is described above, but the above-described embodiment is presented as an example and not intended to limit the scope of the invention. The above-described novel embodiment may be achieved in other various forms and may be omitted, replaced, and changed in various manners without departing from the spirit of the invention. The above-described embodiment is included in the scope and spirit of the invention and also included in the invention recited in the claims and equivalents thereof.

For example, the liquid discharge device 100 is not limited to an aspect in which an image is formed by adhering liquid onto the recording medium 16. For example, the liquid discharge device 100 may be a stereoscopic shaping device of an inkjet scheme. In this case, for example, the liquid discharge device can be used as a stereoscopic shaping device (three-dimensional shaping device) configured to discharge shaping liquid onto a powder layer in which powder is layered to shape a stereoscopic shaped object (three-dimensional shaped object). Alternatively, the liquid discharge device may be a stereoscopic shaping device configured to discharge shaping liquid for shaping a stereoscopic shaped object and form the shaped object by discharging the shaping liquid into a stack.

The liquid discharge device 100 according to the present embodiment is not limited to visualization of a meaningful image such as a character or a figure by discharged liquid. For example, formation of a meaningless pattern or the like and shaping of a three-dimensional image are also included.

The recording medium 16 means a medium to which liquid can at least temporarily adhere, such as a medium to which liquid can adhere and be fixed or a medium that liquid can adhere to and permeate. Specific examples thereof include recording media such as a sheet, record paper, a record sheet, a film, and cloth, electronic components such as an electronic substrate and a piezoelectric element, and media such as a powder layer, an organ model, and an examination cell, and include all media to which liquid can adhere when not particularly limited otherwise.

The material of the recording medium 16 may be a material to which liquid can at least temporarily adhere, such as paper, thread, fiber, cloth, leather, metal, plastic, glass, wood, or ceramic.

For example, control operation of each component included in the liquid discharge device 100 according to the above-described embodiment may be executed by using hardware, software, or a composite configuration thereof.

When processing is executed by using software, a computer program in which a sequence of processing is recorded may be installed and executed on a memory in a computer incorporated in dedicated hardware. Alternatively, the computer program may be installed and executed on a memory in a general-purpose computer capable of executing various kinds of processing.

For example, the computer program may be recorded on a recording medium such as a hard disk or a read only memory (ROM) in advance. Alternatively, the computer program may be temporarily or permanently stored (recorded) on a removable recording medium. Such a removable recording medium may be provided as what is called packaged software. Examples of the removable recording medium include various recording media such as a magnetic disk and a semiconductor memory.

The computer program is installed onto a computer from a removable recording medium as described above. Alternatively, the computer program is wirelessly forwarded onto the computer from a download site. Alternatively, the computer program is forwarded onto a computer through a network in a wired manner.

According to an embodiment, it is possible to obtain highly accurate color image data with a simple configuration.

The above-described embodiments are illustrative and do not limit the present invention. Thus, numerous additional modifications and variations are possible in light of the above teachings. For example, at least one element of different illustrative and exemplary embodiments herein may be combined with each other or substituted for each other within the scope of this disclosure and appended claims. Further, features of components of the embodiments, such as the number, the position, and the shape are not limited the embodiments and thus may be preferably set. It is therefore to be understood that within the scope of the appended claims, the disclosure of the present invention may be practiced otherwise than as specifically described herein.

The method steps, processes, or operations described herein are not to be construed as necessarily requiring their performance in the particular order discussed or illustrated, unless specifically identified as an order of performance or clearly identified through the context. It is also to be understood that additional or alternative steps may be employed.

Further, any of the above-described apparatus, devices or units can be implemented as a hardware apparatus, such as a special-purpose circuit or device, or as a hardware/software combination, such as a processor executing a software program.

Further, as described above, any one of the above-described and other methods of the present invention may be embodied in the form of a computer program stored in any kind of storage medium. Examples of storage mediums include, but are not limited to, flexible disk, hard disk, optical discs, magneto-optical discs, magnetic tapes, nonvolatile memory, semiconductor memory, read-only-memory (ROM), etc.

Alternatively, any one of the above-described and other methods of the present invention may be implemented by an application specific integrated circuit (ASIC), a digital signal processor (DSP) or a field programmable gate array (FPGA), prepared by interconnecting an appropriate network of conventional component circuits or by a combination thereof with one or more conventional general purpose microprocessors or signal processors programmed accordingly.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA) and conventional circuit components arranged to perform the recited functions.

What is claimed is:

1. An image capturing device comprising:
an image capturing unit including a single-plate image sensor including color filters disposed on two-dimensionally arrayed light receiving elements, the image capturing unit being configured to capture an image of an image capturing region on an image capturing target;
a movement control unit configured to move the image capturing region such that images of each of a plurality of pixel areas on the image capturing target are captured by light receiving elements corresponding to respective color filters of colors different from each other;
an acquisition unit configured to acquire image data of the image capturing region each time the image capturing region is moved; and
a generation unit configured to generate color image data of the image capturing region from a plurality of pieces of the image data.

2. The image capturing device according to claim 1, further comprising a first drive unit configured to relatively move at least one of the image capturing target and the image capturing unit in a main-scanning direction and a sub-scanning direction orthogonal to the main-scanning direction, wherein
the movement control unit is configured to control the first drive unit to move the image capturing region.

3. The image capturing device according to claim 2, wherein the movement control unit includes:
a calculation unit configured to calculate an amount of each movement of the image capturing region in at least one of the main-scanning direction and the sub-scanning direction, based on an array interval of the light receiving elements of the image sensor and a distance between the image capturing unit and the image capturing target; and
a movement unit configured to move the image capturing region by the amount of movement.

4. The image capturing device according to claim 2, wherein
the movement control unit is configured to move, for each of image capturing areas on the image capturing target, the image capturing region in a first main-scanning direction as one of directions along the main-scanning direction, in a first sub-scanning direction as one of directions along the sub-scanning direction, and then in a second main-scanning direction as the other direction along the main-scanning direction,
the acquisition unit is configured to acquire, for each of the image capturing areas, the image data each time the image capturing region is moved, and
the generation unit is configured to generate, for each of the image capturing areas, the color image data from a plurality of pieces of the image data.

5. The image capturing device according to claim 1, further comprising a second drive unit configured to change a distance between the image capturing target and the image capturing unit, wherein
the acquisition unit is configured to control the second drive unit to acquire the image data in which a focal point of the image capturing unit coincides with the image capturing target.

6. The image capturing device according to claim 1, wherein the image sensor includes a Bayer array of the color filters of RGB colors.

7. The image capturing device according to claim 1, wherein the image sensor includes a complementary color filter array of the color filters of CMYG colors.

8. A liquid discharge device comprising:
the image capturing device according to claim 1; and
a record head configured to discharge liquid onto a recording medium as the image capturing target.

9. An image capturing method comprising:
moving, by an image capturing unit including a single-plate image sensor including color filters disposed on two-dimensionally arrayed light receiving elements and configured to capture an image of an image capturing region on an image capturing target, the image capturing region such that images of each of a plurality of pixel areas on the image capturing target are captured by light receiving elements corresponding to respective color filters of colors different from each other;
acquiring image data of the image capturing region each time the image capturing region is moved; and
generating color image data of the image capturing region from a plurality of pieces of the image data.
